(19) United States
(12) Patent Application Publication
(10) Pub. No.: US 2017/0077114 A1
(43) Pub. Date: Mar. 16, 2017

(54) SEMICONDUCTOR MEMORY DEVICE

(71) Applicant: KABUSHIKI KAISHA TOSHIBA, Tokyo (JP)

(72) Inventors: Hiromasa YOSHIMORI, Yokohama Kanagawa (JP); Hiroshi SHINOHARA, Yokosuka Kanawaga (JP)

(21) Appl. No.: 15/233,671

(22) Filed: Aug. 10, 2016

(30) Foreign Application Priority Data
Sep. 10, 2015 (JP) 2015-178674

(51) Int. Cl. H01L 27/115; H01L 23/522; H01L 23/528

(52) U.S. Cl. CPC H01L 27/11556; H01L 27/11529; H01L 23/528; H01L 23/5226

(57) ABSTRACT

A semiconductor memory device includes a first word line that is provided above a semiconductor substrate, a second word line that is provided above the first word line, a plurality of semiconductor pillars that are provided on the semiconductor substrate, and pass through the first and second word lines, and first and second plugs that are provided so that the plurality of semiconductor pillars are interposed therebetween. The semiconductor substrate includes an insulating region that is provided deeper than a bottom of the first plug relative to a surface of the semiconductor substrate, between the first plug and one of the semiconductor pillars.

### CROSS-REFERENCE TO RELATED APPLICATION

This application is based upon and claims the benefit of priority from Japanese Patent Application No. 2015-178674, filed Sep. 10, 2015, the entire contents of which are incorporated herein by reference.

### FIELD

Embodiments described herein relate generally to a semiconductor memory device.

### BACKGROUND

In the related art, a NAND flash memory in which memory cells are arranged in three dimensions is known.

### DESCRIPTION OF THE DRAWINGS

FIG. 1 is a block diagram of a semiconductor memory device according to a first embodiment.

FIG. 2 is a circuit diagram of a memory cell array in the semiconductor memory device according to the first embodiment.

FIG. 3 is a layout diagram of the memory cell array in the semiconductor memory device according to the first embodiment.

FIG. 4 is a cross-sectional view of the memory cell array in the semiconductor memory device according to the first embodiment.

FIG. 5 is a cross-sectional view illustrating a manufacturing process of the semiconductor memory device according to the first embodiment.

FIG. 6 is a cross-sectional view illustrating a manufacturing process of the semiconductor memory device according to the first embodiment, following FIG. 5.

FIG. 7 is a cross-sectional view illustrating a manufacturing process of the semiconductor memory device according to the first embodiment, following FIG. 6.

FIG. 8 is a cross-sectional view illustrating a manufacturing process of the semiconductor memory device according to the first embodiment, following FIG. 7.

FIG. 9 is a cross-sectional view illustrating a manufacturing process of the semiconductor memory device according to the first embodiment, following FIG. 8.

FIG. 10 is a cross-sectional view of the memory cell array included in a semiconductor memory device according to a second embodiment.

### DETAILED DESCRIPTION

Embodiments provide a semiconductor memory device capable of improving reliability of data stored therein.

In general, according to one embodiment, a semiconductor memory device includes: a first word line that is provided above a semiconductor substrate; a second word line that is provided above the first word line; a plurality of semiconductor pillars that are provided on the semiconductor substrate, and pass through the first word line and the second word line; and a first plug and a second plug that are provided on the semiconductor substrate so that the plurality of semiconductor pillars are interposed therebetween. The semiconductor substrate includes a first insulating region that is provided deeper than a bottom of the first plug relative to a surface of the semiconductor substrate, between the first plug and one of the semiconductor pillars.

Hereinafter, embodiments will be described with reference to the drawings. Further, in the following description, components having the same functions and configurations are denoted by common reference numerals.

### 1. First Embodiment

In a semiconductor memory device according to a first embodiment, an insulating region, which is formed in a deep groove, is provided between a memory hole and an impurity diffusion region on the semiconductor substrate, that connects a source line and a well line. The insulating region suppresses the diffusion of an impurity from the impurity diffusion region into the bottom of the memory hole during heat treatment.

1-1. Configuration

1-1-1. Overall Configuration

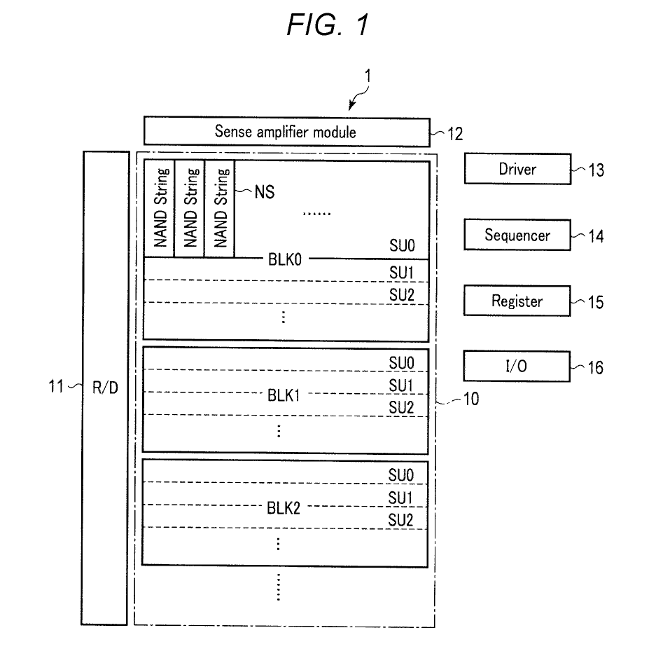

The overall configuration of a semiconductor memory device 1 will be described with reference to FIG. 1.

The semiconductor memory device 1 includes a memory cell array 10, a row decoder (R/D) 11, a sense amplifier module 12, a driver 13, a sequencer (controller) 14, a register 15, and an input and output circuit (I/O) 16.

The memory cell array 10 includes a plurality of blocks BLK (BLK0, BLK1, BLK2, and . . . ), each of which includes a plurality of non-volatile memory cells which are associated with word lines and bit lines. The block BLK is, for example, an erase unit of data, which means that data in the same block BLK is collectively erased. Each block BLK includes a plurality of string units SU (SU0, SU1, SU2, and . . . ), each of which includes a set of NAND strings NS and in each NAND string, memory cells are connected in series. The number of blocks in the memory cell array 10 and the number of string units SU in one block BLK can be any positive number. In the following description, the region of the memory cell array 10 is a cell region, and the region of the other peripheral circuit is a peripheral region.

The row decoder 11 decodes a block address and a page address, selects the word line WL of any corresponding block BLK, and applies an appropriate voltage to a selected word line and a non-selected word line.

The sense amplifier module 12 senses data read from the memory cell through the bit line BL during data reading, and transfers write data to the memory cell through the bit line BL during data writing.

The driver 13 generates a voltage required for writing and reading data, and supplies the voltage to the row decoder 11 and the sense amplifier module 12. This voltage is applied to the various wirings in the memory cell array 10.

The sequencer 14 controls the operation of the entire semiconductor memory device 1.

The register 15 stores various signals. For example, register 15 stores the status of the data writing or erasing operation, and notifies an external controller (not illustrated) whether the operation has successfully completed based on the status. Further, the register 15 can store the command or the address received from the external controller, and also store various tables.

The input and output circuit 16 exchanges data with the external controller or a host apparatus (not illustrated). The input and output circuit 16 outputs the read data which is sensed by the sense amplifier module 12 during data reading, to the external devices, and transfers the write data which is received from the external devices to the sense amplifier module 12 during data writing.

1-1-2. Circuit Configuration of Memory Cell Array

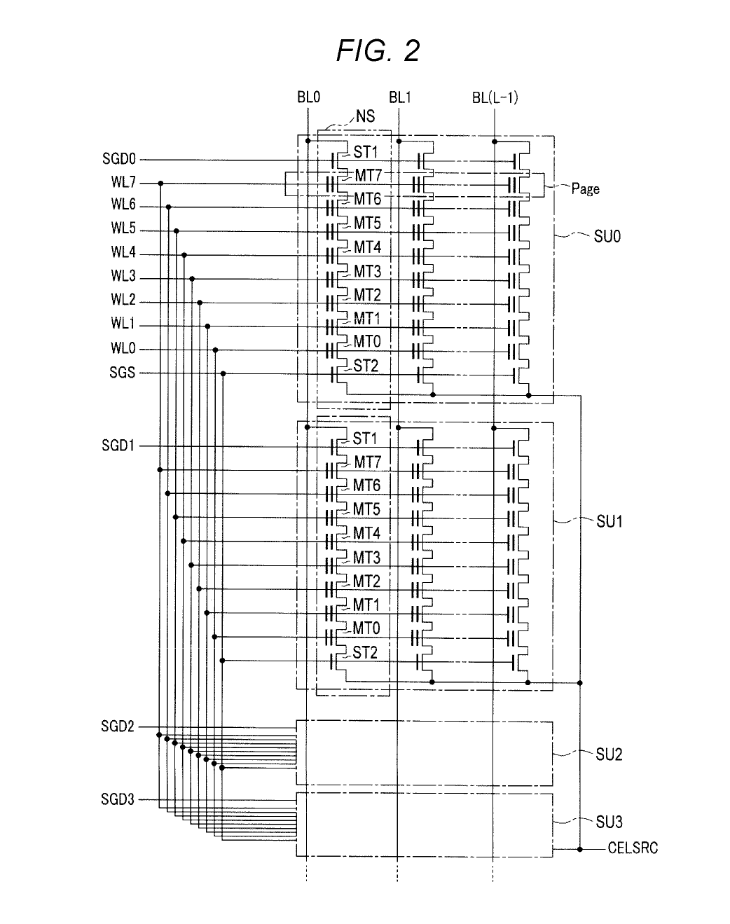

The circuit configuration of the memory cell array 10 will be described with reference to FIG. 2. In FIG. 2, one block BLK included in the memory cell array 10 is illustrated, and the other block BLKs also have the same configuration.

First, the elements provided in the memory cell array 10 will be described.

The block BLK includes, for example, four string units SU (SU0 to SU3). Each of the string units SU includes a plurality of NAND strings NS. Each of the NAND strings NS includes, for example, eight memory cell transistors MT (MT0 to MT7), and select transistors ST1, ST2.

The memory cell transistor MT includes a control gate and a charge storage layer, and stores data in a nonvolatile manner. The memory cell transistors MT0 to MT7 are connected in series. The select transistors ST1, ST2 are used to select a NAND string NS on which data reading or writing is carried out. One ends of the select transistors ST1, ST2 are respectively connected to one ends of the memory cell transistors MT7, MT0.

Next, wirings provided in the memory cell array 10 will be described.

Bit lines BL, word lines WL, select gate lines SGD, SGS, and a source line CELSRC are provided in the memory cell array 10.

For example, L (L is a natural number of 1 or more) bit lines BL are provided. Respective bit lines BL are connected in common to the other end of the select transistor ST1 included in the NAND string NS corresponding to the same column, in each string unit SU.

For example, eight (word lines WL0 to WL7) word lines WL are provided. The respective word lines WL0 to WL7 are connected in common to the control gate of the memory cell transistors MT0 to MT7 included in each string unit SU.

For example, four (select gate lines SGD0 to SGD3) select gate lines SGD are provided. The respective select gate lines SGD0 to SGD3 are connected to the gates of the select transistors ST1 included in the string units SU0 to SU3.

For example, one select gate line SGS is provided. The select gate line SGS is connected in common to the gates of the select transistors ST2 included in each string unit SU.

The source line CELSRC is provided in common between, for example, a plurality of blocks BLK. The source line CELSRC is connected in common to the other end of the select transistors ST2 included in each string unit SU.

In addition, data reading and writing are collectively performed for a group of memory cell transistors MT connected to the same word line WL and referred to as a page, which represents the unit of data reading and writing.

Further, the number of NAND strings NS included in one string unit SU and the number of memory cell transistors MT included in one NAND string NS are not limited as described herein, and can be any positive number.

1-1-3. Planar Layout of Memory Cell Array 10

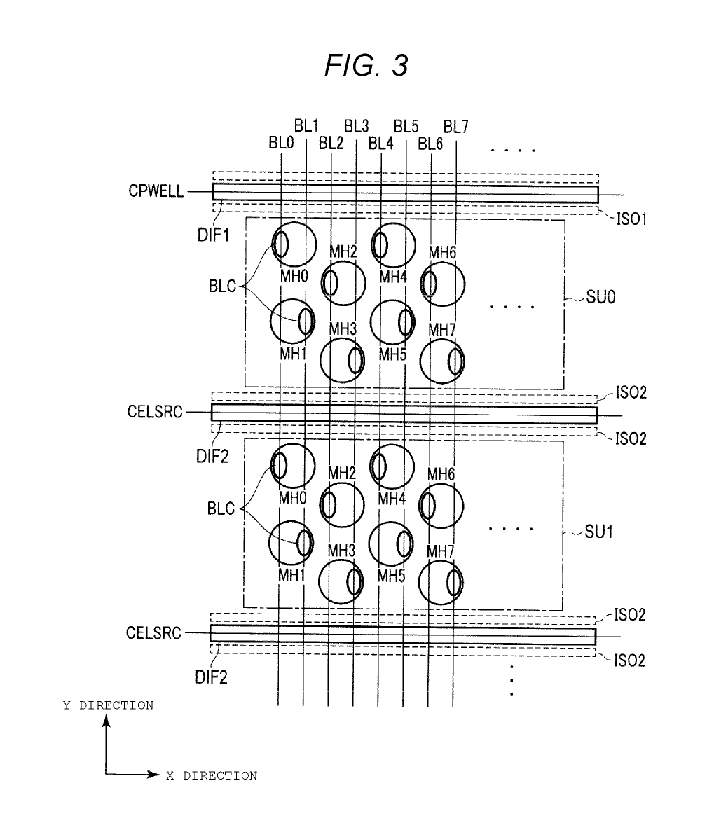

The planar layout of the memory cell array 10 will be described with reference to FIG. 3. FIG. 3 illustrates two string units SU (SU0, SU1).

A plurality of memory holes MH are arranged in a staggered pattern in an XY plane in each string unit SU. One memory hole MH corresponds to a single NAND string NS. FIG. 3 illustrates eight memory holes MH (MH0 to MH7) for each string unit SU. For example, two bit lines BL are provided above each memory hole MH. The bit lines BL0 to BL7 are respectively connected to the semiconductor pillar formed in the memory holes MH0 to MH7 through a bit line contact BLC.

The string unit SU0 is provided between, for example, the impurity diffusion regions DIF1, DIF2, and the string unit SU1 is provided between, for example, two impurity diffusion regions DIF2. The impurity diffusion region DIF1 is p+ type impurity diffusion region on which for example, a 13-group element (III-group element) such as boron (B) is doped, and a well line CPWELL is provided on the impurity diffusion region DIF1. The impurity diffusion region DIF2 is n+ type impurity diffusion region on which for example, a 15-group element (V-group element) such as arsenic (AS) and phosphorous (P) is doped, and a source line CELSRC is provided on the impurity diffusion region DIF2.

Insulating regions ISO1, ISO2 are respectively provided between the impurity diffusion regions DIF1 and string unit SU, and between the impurity diffusion region DIF2 and the string unit SU. The insulating regions ISO1, ISO2 are made of insulators, and are formed by embedding, for example, a silicon oxide film (SiO₂) in the deep groove formed in the surface of the semiconductor substrate.

The memory holes MH illustrated herein are arranged in a staggered pattern, but the layout of the memory hole MH may be in a matrix configuration in alternative embodiments.

Furthermore, the arrangement of the impurity diffusion regions DIF1, DIF2 are not limited as described herein, and various changes are possible depending on the layout of the well line CPWELL and the source line CELSRC.

1-1-4. Sectional Structure of Memory Cell Array 10

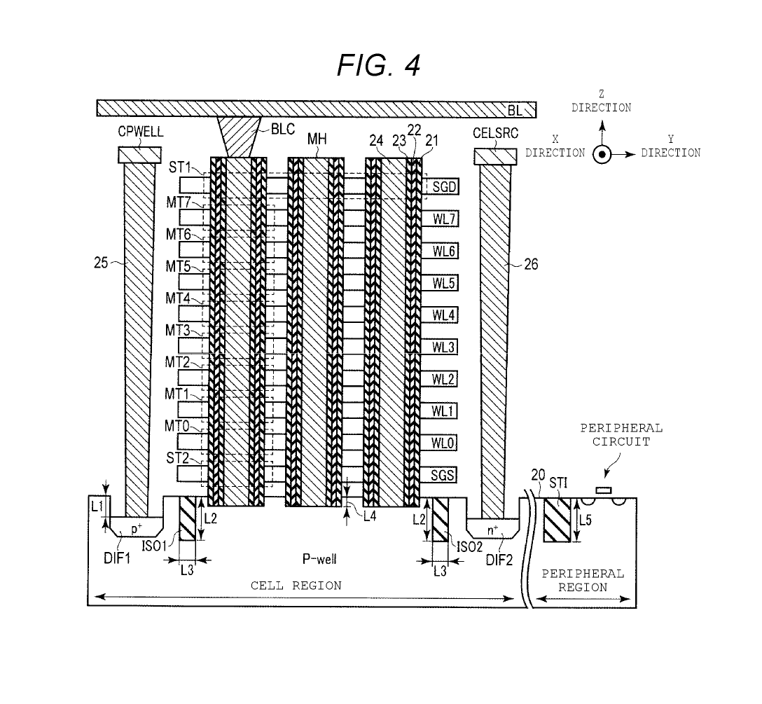

The sectional structure of the semiconductor memory device 1 will be described with reference to FIG. 4. FIG. 4 illustrates a cell region and a peripheral region of the memory cell array 10.

First, the sectional structure of the cell region will be described. FIG. 4 illustrates a sectional structure in which the three memory holes MH are included in a single string unit SU, as an example.

A p-type well region 20 is formed on a semiconductor substrate. The select gate line SGS is provided above the p-type well region 20. The word lines WL0 to WL7 are provided above the select gate line SGS. The select gate line SGD is provided above the word lines WL0 to WL7. The bit line BL is provided above the select gate line SGD. The well line CPWELL and the source line CELSRC are provided on a wiring layer between the bit line BL and the select gate line SGD. The well line CPWELL and the source line CELSRC are respectively connected to the impurity diffusion regions DIF1, DIF2, through contact plugs 25, 26 containing conductive material.

The memory hole MH is formed to pass through the select gate line SGD, the word line WL and the source line SGS, to a position deeper than the upper surface of the p-type well region 20 by L4 (for example, 10 nm to 50 nm) along a Z direction. A block insulating film. 21, an insulating film (charge storage layer) 22, and a tunnel oxide film 23 are provided in order on the side surface of the memory hole MH. A semiconductor pillar 24 containing a conductive material is provided on the inner side than the tunnel oxide film 23. The semiconductor pillar 24 is, for example, non-doped polysilicon, and is a current path of the NAND string NS. Further, the semiconductor pillar 24 is connected to a corresponding single bit line BL, through the bit line contact BLC.

A plurality of the structures described above are arranged in the X direction, and function as a single string unit SU. Further, the select gate lines SGD, SGS and the word lines WL are formed into a plate-like shape that extends in the X direction and the Y direction, and the contact plugs 25, 26 are formed into a plate-like shape extended in the X direction and the Z direction.

The impurity diffusion regions DIF1, DIF2 are formed on the bottom of a region deeper than the upper surface of the p-type well region 20 by L1 (for example, 30 nm to 100 nm), and the insulating regions ISO1, ISO2 are formed to have a depth L2 (for example, 300 nm to 400 nm) from the upper surface of the p-type well region 20 and a width L3 (for example, 40 nm to 100 nm). Further, it is preferable that the width L3 is 80 nm or less in order to avoid the insulating regions ISO1, ISO2 from being in contact with the memory hole MH.

As described above, the insulating region ISO1 is provided deeper than the bottom of the contact plug 25 from the surface of the semiconductor substrate, between the memory hole MH and the contact plug 25. The insulating region ISO2 is provided between the memory hole MH and the contact plug 26, deeper than the bottom of the contact plug 26 from the surface of the semiconductor substrate.

Next, the sectional structure of the peripheral region will be described. FIG. 4 illustrates an element isolation region STI that is formed in the peripheral region of the memory cell array 10, and one transistor which is a peripheral circuit, as an example.

The element isolation region STI is provided in order to separate, for example, the cell region and the peripheral region. Further, the element isolation region STI has a shallow trench isolation (STI) structure, and is formed by embedding an oxide film in a groove provided in the surface of the semiconductor substrate. The depth L5 of the element isolation region STI is substantially equal to the depths of the insulating regions ISO1, ISO2. The depth of the element isolation region STI and the depths of the insulating regions ISO1, ISO2 may be different, and are not particularly limited.

Further, the insulating regions ISO1, ISO2 and the element isolation region STI are collectively formed through, for example, the same process. Accordingly, the materials of the insulating regions ISO1, ISO2 and the oxide film embedded in the element isolation region STI are the same.

Further, the memory cell array 10 may have other configurations, such as the configurations described in, for example, U.S. patent application Ser. No. 12/407,403 filed on Mar. 19, 2009, entitled “three-dimensional stacked non-volatile semiconductor memory,” U.S. patent application Ser. No. 12/406,524 filed on Mar. 18, 2009, entitled “three-dimensional stacked non-volatile semiconductor memory,” U.S. patent application Ser. No. 12/679,991 filed on Mar. 25, 2010, entitled “non-volatile semiconductor memory device and manufacturing method thereof,” and U.S. patent application Ser. No. 12/532,030 filed on Mar. 23, 2009, entitled “semiconductor memory and manufacturing method thereof.” All of these patent applications are incorporated by reference herein in their entirety.

1-2. Manufacturing Method

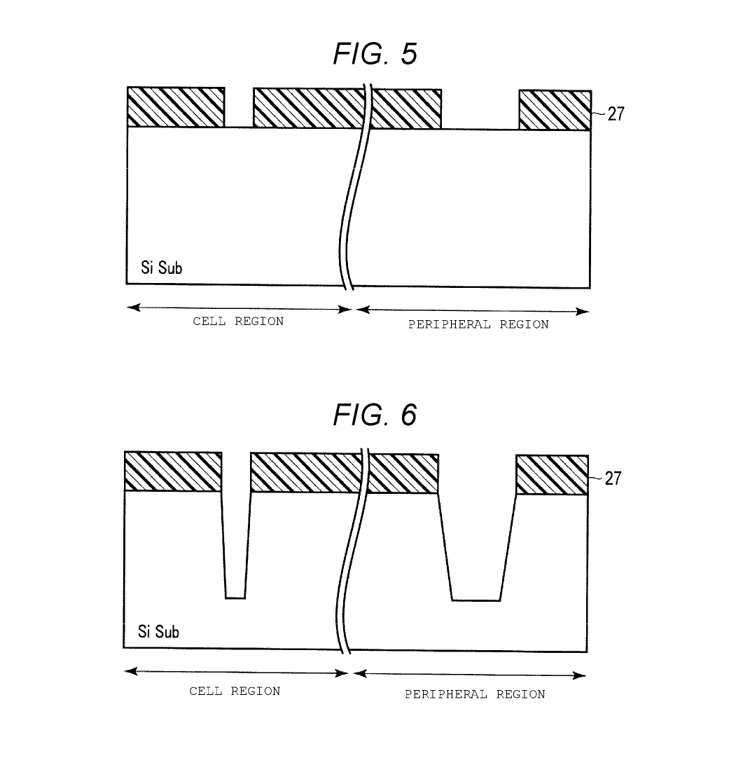

The manufacturing method of the insulating region and the element isolation region will be described with reference to FIG. 5 to FIG. 9. The manufacturing processes of the insulating region ISO1 and the element isolation region STI are respectively depicted in the cell region and the peripheral region, which are illustrated in FIG. 5 to FIG. 9. Because the manufacturing process of the insulating region ISO2 is the same as that of the insulating region ISO1, a description thereof will be omitted.

First, as illustrated in FIG. 5, a resist 27 formed on the semiconductor substrate is patterned by a photolithography method.

Next, as illustrated in FIG. 6, the surface of the semiconductor substrate is etched by anisotropic etching, with the resist 27 as a mask. For example, ion beam etching (IBE), reactive ion etching (RIE), or the like are used as the anisotropic etching. Thus, a groove is formed on the surface of the semiconductor substrate.

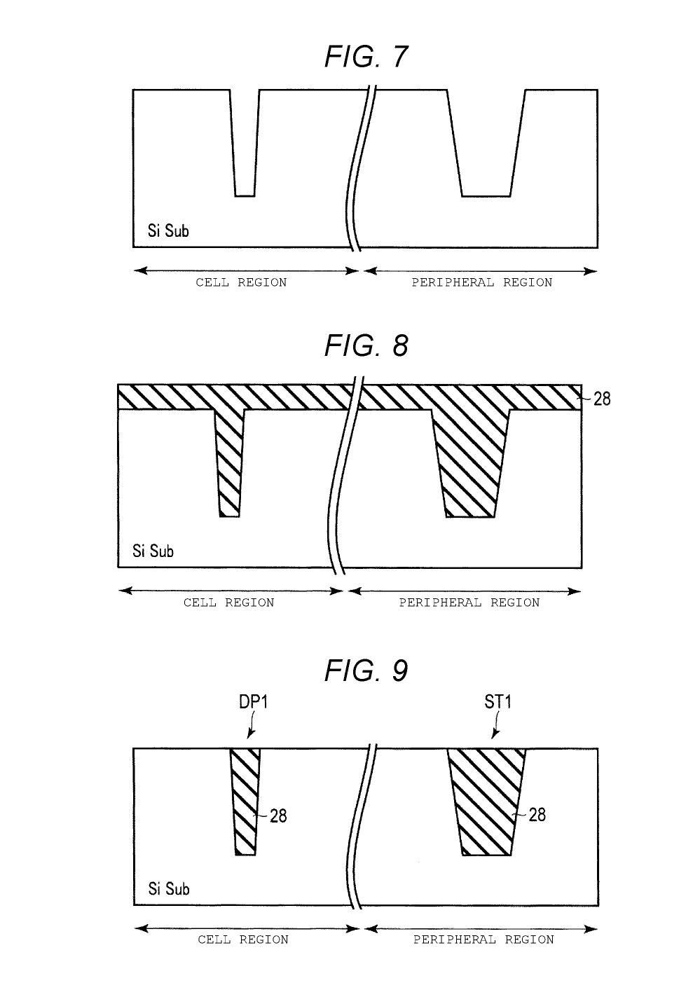

Next, as illustrated in FIG. 7, the resist 27 remaining on the semiconductor substrate is removed.

Next, as illustrated in FIG. 8, an oxide film 28 is formed so as to cover the surface of the semiconductor substrate, by for example, the chemical vapor deposition (CVD). The oxide film 28 is, for example, a silicon oxide film (SiO₂).

Next, as illustrated in FIG. 9, the oxide film 28 on the surface of the semiconductor substrate is removed, by for example, chemical mechanical polishing (CMP) or the like, and the oxide film 28 is embedded in the groove portions corresponding to the insulating region ISO1 and the element isolation region STI.

As described above, the insulating region ISO1 and the element isolation region STI are formed simultaneously. After this, conventional manufacturing processes are carried out to form the memory cell array 10 on the semiconductor substrate.

1-3. Effect of First Embodiment

In the semiconductor memory device on which memory cells are stacked, ions of 13-group elements such as boron and 15-group elements such as arsenic are respectively implanted to a portion connecting the source line CELSRC to the semiconductor substrate and a portion connecting the well line CPWELL to the semiconductor substrate in order to maintain a potential.

However, the impurity may be diffused to the bottom of the memory hole MH as a result of the heat treatment for activating the implanted ions, and thus the threshold voltage of the select transistor ST2 located in the bottom of the memory hole MH varies in some cases. If the threshold voltage of the select transistor ST2 varies and changes, variations may occur in the amount of current flowing through the select transistor ST2 between the NAND strings in the same string unit SU during various operations. Thus, the reliability of the data of the semiconductor memory device is sometimes deteriorated.

Thus, in the semiconductor memory device 1 according to the first embodiment, the insulating regions ISO1, ISO2 are respectively provided between the memory hole MH and the impurity diffusion regions DIF1, DIF2 of the string unit SU, as illustrated in FIG. 4. The insulating regions ISO1, ISO2 are formed, prior to the heat treatment for activating the ions implanted to the impurity diffusion regions DIF1, DIF2, and suppresses the diffusion of impurities to the bottom of the memory hole MH as a result of the heat treatment.

Therefore, it is possible to suppress the change in the threshold voltage of the select transistor ST2, due to the impurity diffusion, in the semiconductor memory device 1 according to the first embodiment, and it is possible to improve reliability of the data of the semiconductor memory device 1.

Incidentally, in the configuration of the semiconductor memory device 1, only one of the insulating regions ISO1, ISO2 may be formed, and the configuration is not limited thereto. For example, since boron is an element being likely to diffuse, it is also effective to form only the insulating region ISO1 corresponding to the impurity diffusion region DIF1 using boron.

### 2. Second Embodiment

A semiconductor memory device 1 according to the second embodiment is different from the semiconductor memory device 1 according to the first embodiment in the widths of the insulating regions ISO1, ISO2.

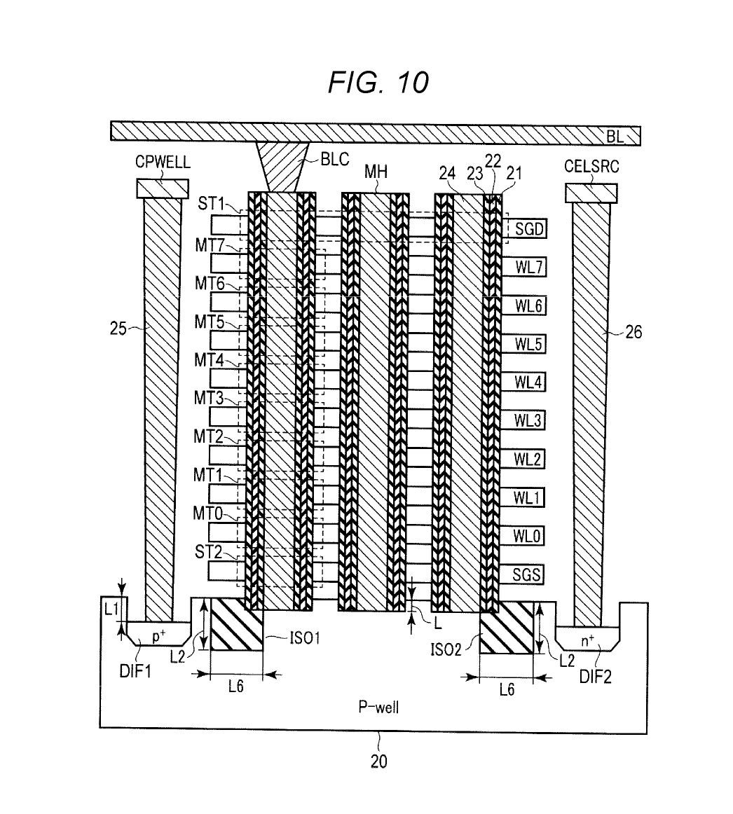

FIG. 10 illustrates the sectional structure of the memory cell array 10 of the second embodiment, with only those features different from the first embodiment described below.

Widths L6 of the insulating regions ISO1, ISO2 in the second embodiment are larger than the widths L3 of the insulating regions ISO1, ISO2 in the first embodiment, and insulating regions ISO1, ISO2 are respectively formed up to the bottom of the memory hole MH.

The interval between the memory hole MH and the impurity diffusion regions DIF1, DIF2 in each string unit SU is narrow in order to reduce the chip area. Therefore, in the case of forming deep grooves corresponding to the insulating regions ISO1, ISO2 in these portions, these portions are likely to be affected from the size variations, the misalignment, and the like in a photolithography method, and the degree of difficulty of achieving precision in the process is increased.

Thus, in the semiconductor memory device 1 according to the second embodiment, the widths of the insulating regions ISO1, ISO2 are increased so as to reach the bottom of the memory hole MH. This can reduce the influence such as the size variations and the misalignment in the photolithography method, and lower the degree of difficulty of the process, and reduce the manufacturing cost.

In addition, the memory hole MH of which the insulating region ISO1 has reached the bottom becomes disabled. In order to reduce the number of memory holes MH that are disabled in this manner, only the insulating region ISO1 corresponding to the impurity diffusion region DIF1 using boron which is likely to diffuse may be formed.

In addition, the widths of the insulating regions ISO1, ISO2 may be different, for example, the width of the insulating region ISO1 may be set as L5, and the width of the insulating region ISO2 may be set as L3.

Thus, it is possible to improve reliability of data of the semiconductor memory device.

Incidentally, embodiments are not limited to the first and second embodiments, and various modifications are possible. For example, the manufacturing process of the semiconductor memory device 1 described above is an example and is not limited to this. Further, in the above description, connection indicates electrical connection, and also includes connection through separate element therebetween.

Further, in the respective embodiments described above,

(1) In the reading operation, the voltage applied to the word line that is selected in an A-level reading operation is for example, in a range of 0 V to 0.55 V. Without being limited thereto, the voltage may be in any one of ranges of 0.1 V to 0.24 V, 0.21 V to 0.31 V, 0.31 V to 0.4 V, 0.4 V to 0.5 V, and 0.5 V to 0.55 V.

The voltage applied to the word line that is selected in a B-level reading operation is, for example, in a range of 1.5 V to 2.3 V. Without being limited thereto, the voltage may be in any one of ranges of 1.65 V to 1.8 V, 1.8 V to 1.95 V, 1.95 V to 2.1 V, and 2.1 V to 2.3 V.

The voltage applied to the word line that is selected in a C-level reading operation is, for example, in a range of 3.0 V to 4.0 V. Without being limited thereto, the voltage may be in any one of ranges of 3.0 V to 3.2 V, 3.2 V to 3.4 V, 3.4 V to 3.5 V, 3.5 V to 3.6 V, and 3.6 V to 4.0 V.

A time (tR) of the reading operation may be, for example, in a range of 25 μs to 38 μs, 38 μs to 70 μs, or 70 μs to 80 μs.

(2) The writing operation includes a program operation and a verification operation as described above. In the writing operation, a voltage that is first applied to the word line, which is selected during a program operation is, for example, in a range of 13.7 V to 14.3 V. Without being limited thereto, the voltage may be in any one of ranges of, for example, 13.7 V to 14.0 V, and 14.0 V to 14.6 V.

A voltage that is first applied to the word line which is selected during a writing to the odd-numbered word line, and a voltage that is first applied to the word line which is selected during a writing to the even-numbered word line may be changed.

When the program operation is performed by an incremental step pulse program (ISPP) method, an example of a step-up voltage is about 0.5 V, or the like.

The voltage applied to the non-selected word line may be in a range of, for example, 6.0 V to 7.3 V. Without being limited thereto, the voltage may be in a range of, for example, 7.3 V to 8.4 V, or may be 6.0 V or less.

The pass voltage to be applied may be changed depending on whether the non-selected word line is an odd-numbered word line or an even-numbered word line.

A time (tProg) of the writing operation may be, for example, in a range of 1,700 μs to 1,800 μs, 1,800 μs to 1,900 μs, or 1,900 μs to 2,000 μs.

(3) In the erase operation, a voltage that is first applied to the well, which is formed on the top of the semiconductor substrate and above which the memory cell is located, is for example, in a range of 12 V to 13.6 V. Without being limited thereto, the voltage may be in a range of, for example, 13.6 V to 14.8 V, 14.8 V to 19.0 V, 19.0 V to 19.8 V, and 19.8 V to 21 V.

A time (tErase) of the erase operation may be, for example, in a range of 3,000 μs to 4,000 μs, 4,000 μs to 5,000 μs, or 4,000 μs to 9,000 μs.

(4) The structure of the memory cell includes a charge storage layer arranged through a tunnel insulating film having a film thickness of 4 nm to 10 nm on the semiconductor substrate (silicon substrate). A stacked structure of an insulating film such as SiN or SiON having a film thickness of 2 nm to 3 nm and polysilicon having a film thickness of 3 nm to 8 nm can be used for the charge storage layer. Moreover, metal such as Ru may be added to the polysilicon. An insulating film is provided above the charge storage layer. The insulating film includes a silicon oxide film having a film thickness of 4 nm to 10 nm which is interposed between a lower layer High-k film having a film thickness of 3 nm to 10 nm and an upper layer High-k film having a film thickness of 3 nm to 10 nm. Examples of the High-k film are HfO or the like. The film thickness of the silicon oxide film can be made thicker than that of the High-k film. A control electrode having a film thickness of 30 nm to 70 nm is provided on the insulating film, through a material having a film thickness of 3 nm to 10 nm. Here, the material is a metal oxide film such as TaO, and a metal nitride film such as TaN. W or the like can be used for the control electrode.

Further, it is possible to form an air gap between the memory cells.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a first word line that is provided above a semiconductor substrate;
a second word line that is provided above the first word line;
a plurality of semiconductor pillars that are provided on the semiconductor substrate, and pass through the first word line and the second word line; and
a first plug and a second plug that are provided on the semiconductor substrate so that the plurality of semiconductor pillars are interposed therebetween,
wherein the semiconductor substrate includes a first insulating region that is provided deeper than a bottom of the first plug relative to a surface of the semiconductor substrate, between the first plug and one of the semiconductor pillars.

2. The device according to claim 1,
wherein the first insulating region is made of a same material as a material of an element isolation region that is provided in a peripheral circuit portion of the semiconductor substrate.

3. The device according to claim 1,
wherein the semiconductor substrate further includes a second insulating region that is provided deeper than a bottom of the second plug relative to the surface of the semiconductor substrate, between the second plug and one of the semiconductor pillars.

4. The device according to claim 3,
wherein the first insulating region and the second insulating region are made of a same material as a material of an element isolation region that is provided in a peripheral circuit portion of the semiconductor substrate.

5. The device according to claim 4,
wherein the material is a silicon oxide film.

6. The device according to claim 3,
wherein widths of the first and second insulating regions are the same.

7. The device according to claim 3,
wherein at least one of the first and second insulating regions extend in a width direction so that an edge thereof is vertically aligned with an edge of one of the semiconductor pillars.

8. The device according to claim 7,
wherein the first and second insulating regions have different widths.

9. The device according to claim 1,
wherein a bottom of the semiconductor pillars is positioned above bottoms of the first plug and the second plug.

10. The device according to claim 1,
wherein the surface of the semiconductor substrate that is in contact with the first plug includes a 13-group element or a 15-group element.

11. A semiconductor memory device comprising:
a first word line that is provided above a semiconductor substrate;
a second word line that is provided above the first word line;
a first semiconductor pillar on the semiconductor substrate and pas sing through the first word line and the second word line;
a second semiconductor pillar on the semiconductor substrate and pas sing through the first word line and the second word line; and
first and second plugs arranged on the semiconductor substrate so that the first and second semiconductor pillars are interposed therebetween, wherein
the semiconductor substrate includes a first insulating region between the first semiconductor pillar and the first plug and a second insulating region between the first semiconductor pillar and the first plug, and
the first and second insulating regions extend deeper into the semiconductor substrate from a surface of the semiconductor substrate than either of the first and second plugs.

12. The device according to claim 11,
wherein widths of the first and second insulating regions are the same.

13. The device according to claim 11,
wherein the first insulating region extends in a width direction so that an edge thereof is vertically aligned with an edge of the first semiconductor pillar and no portion of the first insulating region is below the first semiconductor pillar.

14. The device according to claim 13,
wherein the second insulating region extends in a width direction so that an edge thereof is vertically aligned with an edge of the second semiconductor pillar and no portion of the second insulating region is below the second semiconductor pillar.

15. The device according to claim 11,
wherein the first and second insulating regions have different widths.

16. The device according to claim 11,
wherein bottoms of the first and second semiconductor pillars are positioned below upper surfaces of the first and second insulating regions.

17. The device according to claim 11,
wherein bottoms of the first and second semiconductor pillars are positioned above bottoms of the first and second plugs.

18. The device according to claim 11,
wherein the surface of the semiconductor substrate that is in contact with the first plug includes a 13-group element and the surface of the semiconductor substrate that is in contact with the second plug includes a 15-group element.

19. The device according to claim 11,
wherein the first and second insulating regions are made of a same material as a material of an element isolation region that is provided in a peripheral circuit portion of the semiconductor substrate.

20. The device according to claim 19,
wherein the material is a silicon oxide film.
